(19) United States
(12) Patent Application Publication
(10) Pub. No.: US 2016/0031700 A1
(43) Pub. Date: Feb. 4, 2016

(54) MICROELECTROMECHANICAL MICROPHONE

(71) Applicant: Pixtronix, Inc., San Diego, CA (US)

(72) Inventors: Andrew William Sparks, Cambridge, MA (US); Timothy Brosnihan, Natick, MA (US)

(21) Appl. No.: 14/449,542

(22) Filed: Aug. 1, 2014

(51) Int. Cl. B81B 3/00; B81C 1/00; G09G 5/36; H04R 1/02; H04R 23/00

(52) U.S. Cl. CPC B81B 3/007; H04R 1/028; H04R 23/006; G09G 5/363; B81C 1/00158; H04R 2499/15; H04R 2201/003; G09G 2370/08; B81B 2201/0257; B81B 2203/0127; B81B 2203/0163; B81B 2207/07; B81B 2203/0307

(57) ABSTRACT

This disclosure provides systems, methods and apparatus including microelectromechanical system microphones. In one aspect, the systems include a substrate made of a low dielectric material, such as glass. A layer of semiconductor material extends, substantially continuously over a surface of the substrate and includes an array of display elements that modulate light to form an image and a movable diaphragm that detects acoustic signals. The diaphragm is held away from the substrate by springs that include beams having an aspect ratio of about four to one.

### TECHNICAL FIELD

This disclosure relates to microphones formed as microelectromechanical systems and devices that have microelectromechanical microphones formed thereon.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

MEMS devices can be used to make lightweight, low power portable electronic devices, such as cell phones and tablet computers. Most of these types of portable electronics now have MEMS microphones. These microphones work well but they are separate, individual components that take up space in the device and add to cost.

Typically, the MEMS microphone includes a disc shaped diaphragm that is suspended from a post or frame, similar to a cantilever beam. The diaphragm extends over a ground plane. Acoustic waves cause the diaphragm to move toward and away from the ground plane. This movement can change an electrical characteristic, typically capacitance, and this change can be measured to produce electrical signals representative of the audio signal acting on the diaphragm.

Although existing MEMS microphones work well, there remains a need for improved MEMS microphones that reduce cost, use less space and provide improved performance.

### SUMMARY

The systems, methods and devices of this disclosure each have several innovative aspects, no single one of which is solely responsible for the desirable attributes disclosed herein.

One innovative aspect of the subject matter described in this disclosure can be implemented in microphones that include a substrate and a plurality of anchors attached to the substrate and extending away from the substrate. The microphone has a diaphragm and a plurality of springs connecting at one end to an anchor and at another end to the diaphragm to hold the diaphragm away from the substrate. The spring includes a beam that extends from the anchor to the diaphragm and has a cross-section with an aspect ratio of greater than 4:1, and may be for example between 4:1 and 16:1.

In some implementations, the microphone includes a substrate that may be a low dielectric material. For example, the substrate may be glass, silica, doped silicon or any other material suitable for use as a substrate for semiconductor manufacturing and having a dielectric value generally lower than the dielectric value of amorphous silicon.

In some implementations, the microphone includes a lip facing the substrate and extending along a peripheral edge of the diaphragm. In some implementations, the microphone includes a rib connected to a peripheral edge of the diaphragm to reduce warping of the substrate. In some implementations, the microphone includes a plurality of apertures formed on the diaphragm to reduce air resistance as the diaphragm moves toward the substrate and may include a wall formed along a peripheral edge of an aperture and facing the substrate. In some implementations, the microphone includes a plurality of springs and the springs include two parallel beams joined at respective ends to form a flexible connector. In some implementations, the beams and the diaphragm are integrally formed from a layer of semiconductor material.

In some implementations, the microphone inlcudes display elements formed on the substrate to form a display on the substrate, a processor capable of communicating with the display, the processor being capable of processing image data and a memory device capable of communicating with the processor. In some implementations, the display elements and the springs include a continuous layer of semiconductor material deposited upon the substrate. In some implementations, the microphone includes a driver circuit capable of sending at least one signal to the display and a controller capable of sending at least a portion of the image data to the driver circuit. In some implementations, the microphone includes an image source module capable of sending the image data to the processor, wherein the image source module includes at least one of a receiver, transceiver, and transmitter. In some implementations, the microphone includes an input device capable of receiving input data and communicating the input data to the processor.

In one aspect of the subject matter described herein, a method for manufacturing a microelectromechanical microphone is provided that includes providing a substrate, depositing a mold having a sidewall and a plateau onto the substrate, depositing a semiconductor material on the sidewall and on the plateau, and etching the mold to release the material deposited on the sidewall and the plateau to thereby form a spring attached to a diaphragm. In some implementations, the method forms a silicon beam having a cross-sectional aspect ratio between 4:1 and 16:1 and forms a passivation layer. In some implementaitons, the method connects a portion of the substrate proximate the diaphragm to a ground plane.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIGS. 3A and 3B shows MEMS displays having a MEMS microphone device.

FIG. 4 shows a cross-sectional view of a MEMS display having a MEMS microphone.

FIG. 5 is a plan view of a MEMS microphone.

FIG. 6 shows a perspective view of a MEMS microphone.

FIG. 7 shows a cross-sectional view of the MEMS microphone of FIG. 5.

FIGS. 8A-8E depict a process for forming a sidewall beam technology.

FIG. 9 is a flow chart diagram of one process for forming a MEMS microphone.

FIGS. 10A and 10B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

The devices, systems and methods described herein, in one aspect, include MEMS microphones that include a movable diaphragm that is held proximate to, but away from, a low dielectric substrate. The movable diaphragm is held by a plurality of springs made from resilient beams, such as silicon beams. The resilient silicon beams may have a cross-sectional aspect ratio of at least 4:1. In some implementations, the beam has a cross-sectional aspect ratio in the range of 4:1 to 16:1, including a passivation layer. In some implementations the silicon beam includes a sidewall having a surface shaped by a mold and etched by a mold release etchant to provide a substantially flat surface. In some implementations, the etch process may shape the sidewall and provide a curve or taper to the sidewall. Typically the curve of sidewall extends outward from the edge of the sidewall that is closest to the source of the etchant during the etch process. Typically, the sidewall increases slightly in thickness towards the end of the sidewall that was furthest from the source of the etchant.

In some implementations, the movable diaphragm includes a lip disposed about the peripheral edge of the substrate and positioned to face the glass substrate. The lip may provide a contact surface that reduces the likelihood of stiction binding the diaphragm to the low dielectric substrate.

Particular implementations of the subject matter described in this disclosure can be implemented to realize one or more of the following potential advantages. In one aspect, the MEMS microphone devices are integrally formed into a MEMS layer that includes movable MEMS light modulators. This can reduce the number of process operations and thereby the cost of manufacture and avoid defects that can arise when a separately formed microphone component is connected to a substrate. Additionally, integrally formed components have a smaller package size than separately formed components and this can reduce overall display size. Further, integrally formed microphones can be arranged on peripheral edges of the display and multiple microphones can be formed on the peripheral edge to provide an array of microphones on the display. Arrays of microphones can achieve improved signal to noise ratios.

In another aspect, the MEMS microphone has a movable diaphragm that moves relative to a low dielectric substrate, such as a glass substrate, to provide a microphone having lower parasitic capacitance and improved signal to noise ratios for detected acoustic signals.

In another aspect, the methods described herein provide MEMS microphones through process steps employed to form MEMS light modulators, thereby reducing the need for additional process steps during manufacture.

In one implementation, the MEMS microphone described herein may be formed by processing a layer of semiconductor material deposited on a substrate to form the microphone and to form a plurality of light modulators of the type used in display apparatus.

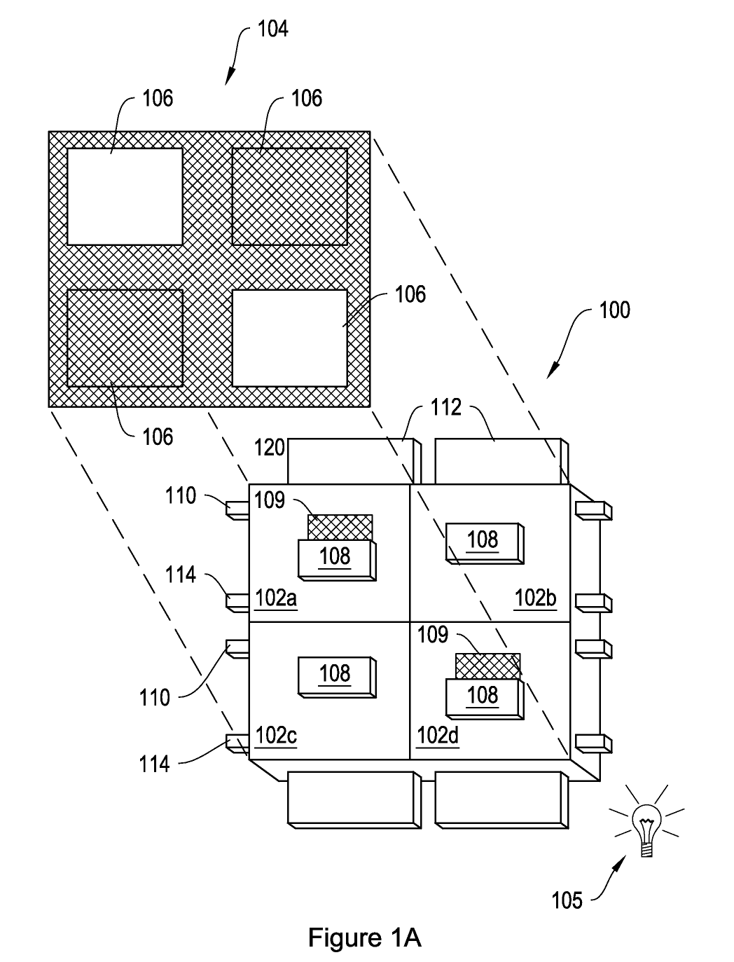

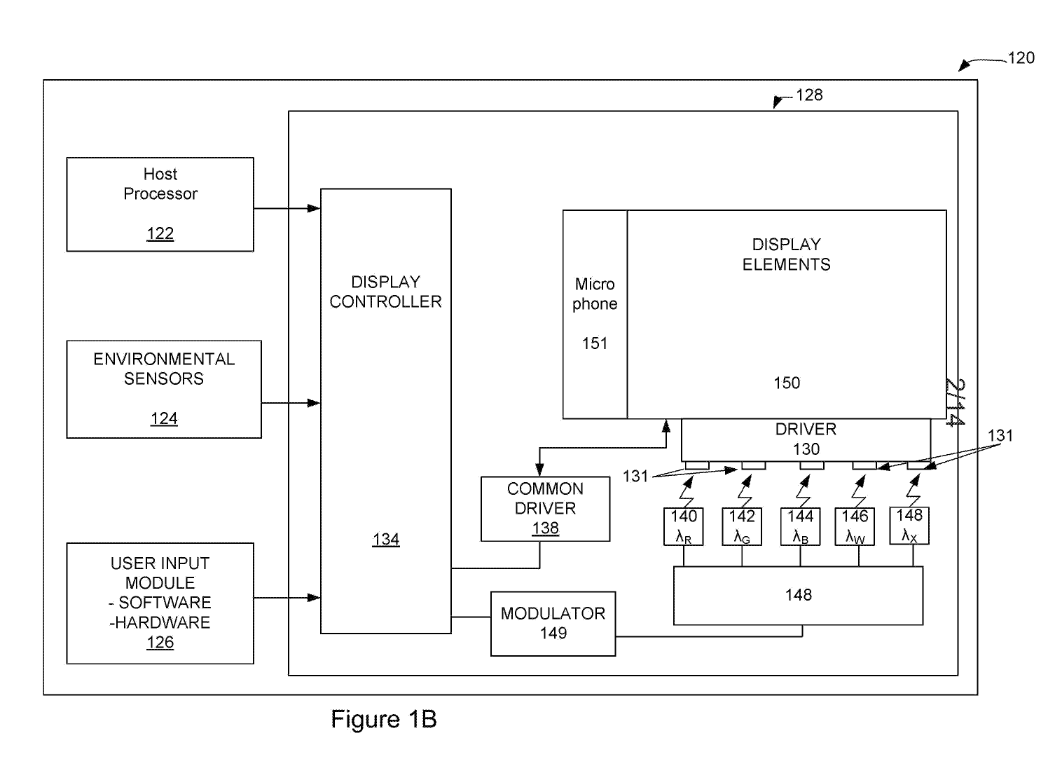

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex®, or other suitable glass material. Typically, such substrates are low-dielectric materials in that the these materials have a lower dielectric value than single crystal silicon, the conventional material employed as a substrate.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148, an array of display elements 150, such as the light modulators 102 shown in FIG. 1A and a microphone 151. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying only a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving and/or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for only a certain fraction of the image is loaded to the array of display elements 150. For example, the sequence can be implemented to address only every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The microphone 151 is shown as a functional block attached to the display elements 150. In one implementation the microphone 151 is a MEMS microphone and may be an integrally formed component within, or adjacent, an array of MEMS display elements 150. The MEMS microphone 151 may be formed on the same substrate and during the same processing steps as the MEMS display elements 150. The microphone 151 may be a MEMS microphone that senses acoustic signals, such as voice, music, and other acoustic signals. The common driver 138 may provide a signal to the microphone 151 that the microphone 151 may modulate in response to acoustic signals acting on the microphone 151. The modulated signal may be passed to the display controller 134 and to the host processor for further processing, such as amplification, voice recognition, or any other type of processing typically done with detected acoustic signals.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; and/or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

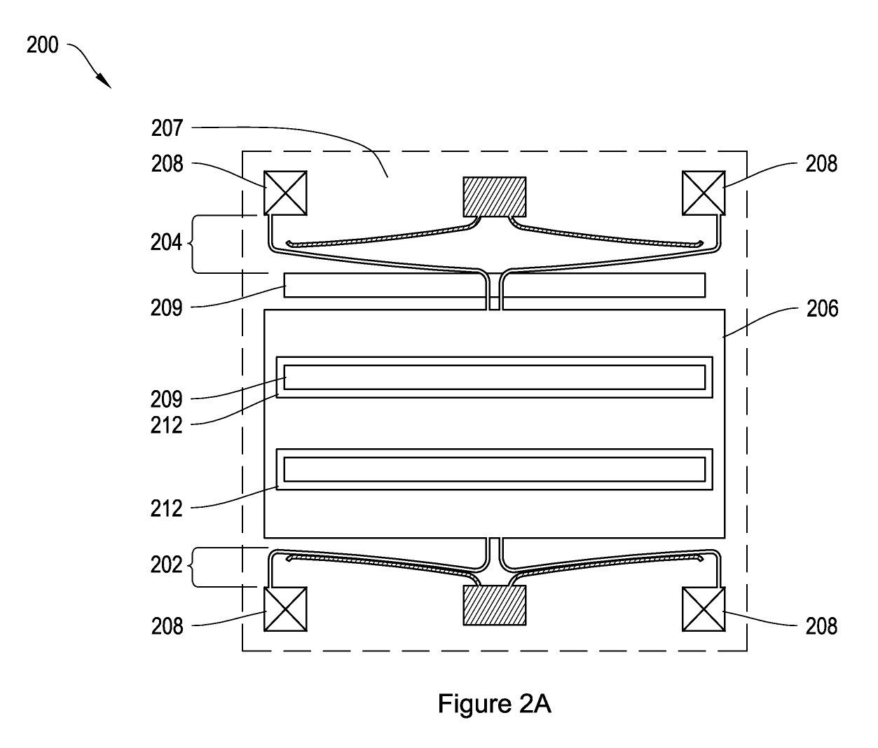

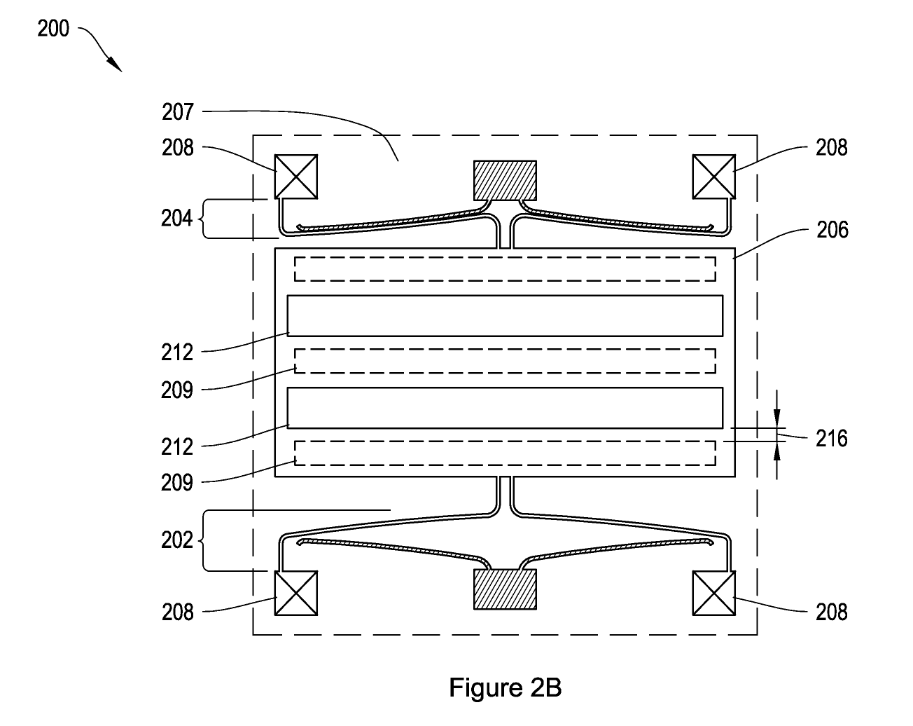

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have only a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

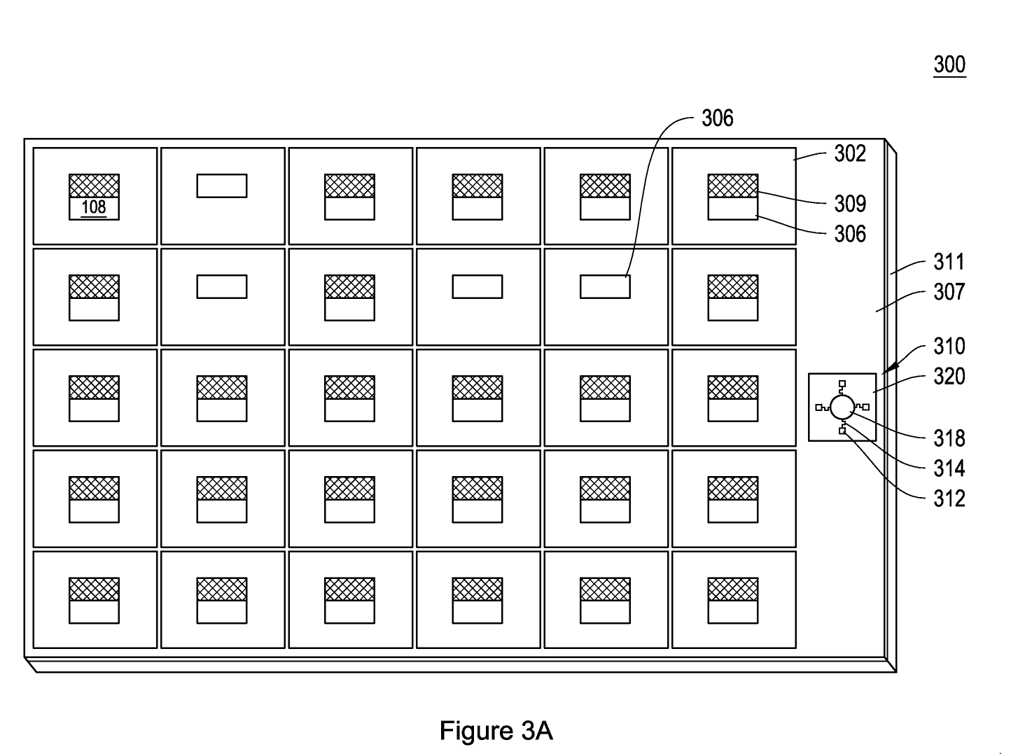

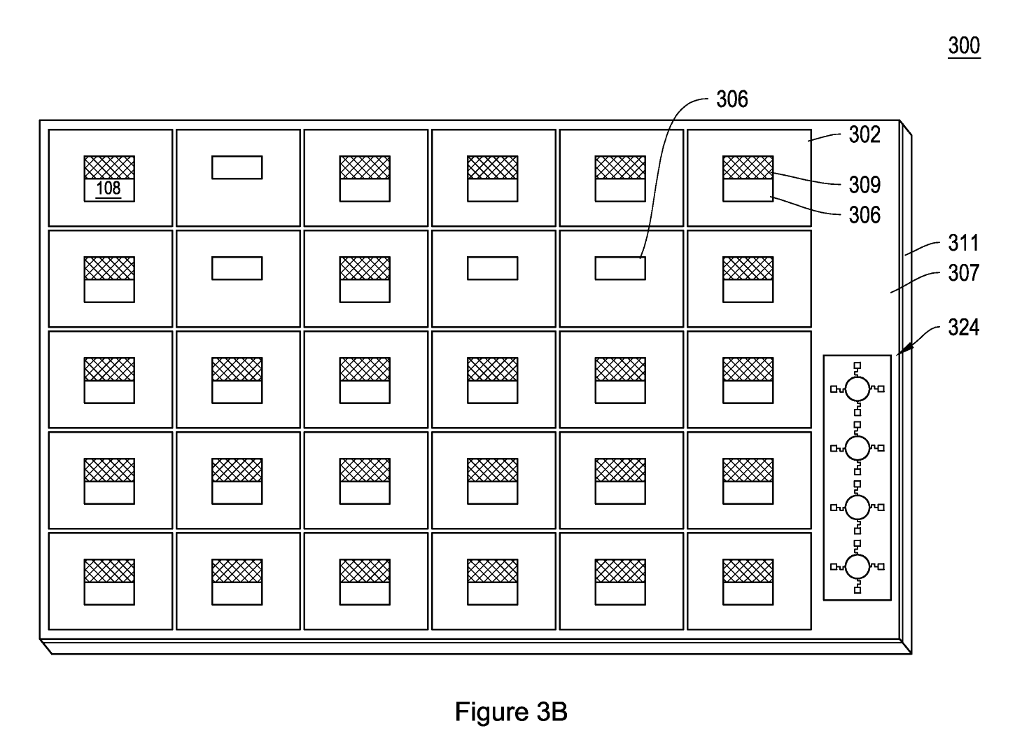

FIGS. 3A and 3B show examples of a MEMS display having a MEMS microphone. In particular, FIG. 3A depicts a MEMS display 300 that includes a plurality of actuators 302 arranged in rows and columns to form a matrix of actuators on an aperture layer 307. The aperture layer 307 may be a layer of semiconductor material deposited on the substrate 311. The substrate 311 may be glass or some other suitable material and in some implementations is a material with a low dielectric constant. The actuators 302 depicted in FIG. 3A can be similar to the actuators 202 described in detail with reference to FIGS. 2A and 2B. The actuators 302 are MEMS shutter assemblies that have shutters 306 that can be moved back and forth over an aperture such as the aperture 309. As described with reference to FIGS. 2A and 2B, by moving the shutters 306 over the apertures 309 light can be blocked from passing through the aperture and on to a cover plate of the display. FIG. 3A shows the shutters in open and closed positions. The shutters 306 that are open are spaced away from the aperture 309 so that the aperture 309 is visible within the actuator 302. The shutters 306 that are closed are moved into alignment with the apertures of 309 so that the aperture 309 is blocked by the shutter 306 and the aperture 309 is not visible when looking down on the actuator 302 in this plan view of FIG. 3A.

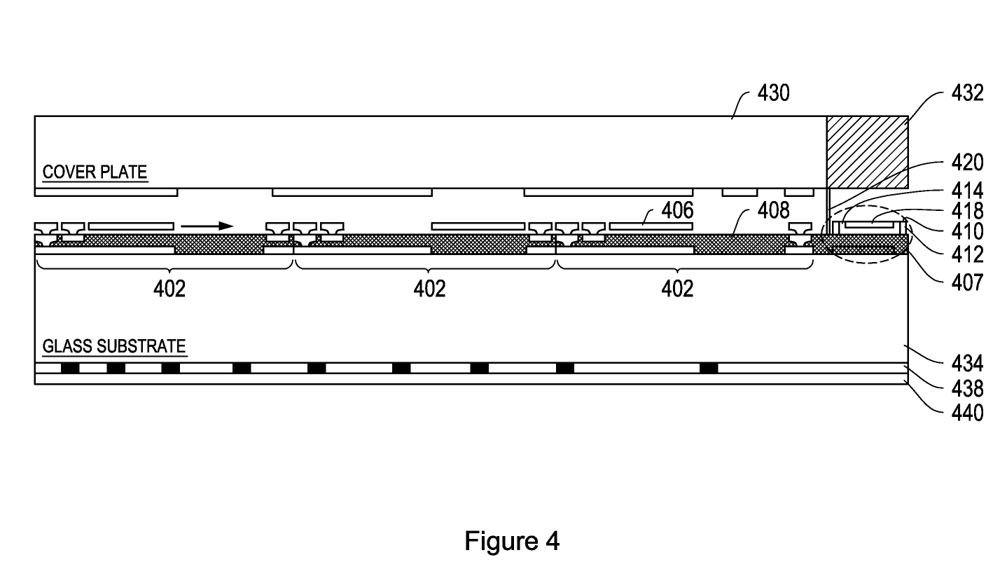

FIG. 3A also includes a microphone 310 that is formed on the aperture layer 307 and placed on a peripheral edge of the aperture layer 307 so that it is physically spaced away from the array of actuators 302. In some implementations, the microphone 310 is spaced 0.25-5 mm from the MEMS shutter assemblies. A seal wall 320 extends around the microphone 310 and seals against a coverplate (not shown). The seal wall 320 prevents fluid, used with some implementations to lubricate the moving shutters, from contacting the microphone 320. The microphone 310 includes anchors 312 that, in this implementation, are arranged at equal distances around the peripheral edge of the microphone 310 so that the four anchors 312 are an equal distance apart from each other. In some implementations, a spring 314 extends from each anchor 312 and connects to a diaphragm 318. The diaphragm 318 is suspended away from the aperture layer 307 and is movable due to the flexible characteristic of the springs 314. Other spring designs may be used. The microphone 310 faces a cover plate, shown in FIG. 4, so that acoustic signals directed toward the display are incident against the diaphragm 318 and will cause the diaphragm 310 to move toward or away from the aperture layer 307. FIG. 3A shows a single microphone on the aperture layer 307, but in other implementations, multiple microphones may be formed on the aperture layer 307.

FIG. 3B shows an array 324 of microphones, each of which may be similar to the microphone 310 shown in FIG. 3A. A seal wall 326 seals against a cover plate (not shown) to prevent fluid covering the MEMS shutters from contacting the microphones in the array 324. The microphone array 324 may include multiple microphones 310 that are wired in parallel as an array of microphones capable of generating a single output signal. This array may reduce the signal to noise ratio of the output signal, Alternatively, the multiple microphones in the array 324 may respectively address different applications. Further alternatively, the array 324 may allow for beam forming and directional capabilities and allow for applications to detect the direction from where sound is coming.

FIG. 4 shows a cross sectional view of one example of a MEMS display having a MEMS microphone. In particular, FIG. 4 depicts a cross sectional view of a MEMS display 400 that has actuators 402 that move a shutter 406 into and out of alignment with an aperture 409. The actuators 402 are formed on an aperture layer 407 that is deposited on a low dielectric substrate, such as glass, silica, plastic or some other low dielectric material. The low dielectric material provides a substrate 434 that in some implementations is transparent and will carry light including light that may reflect off the lower reflective surface 438 and pass through the apertures 409 when the shutters 406 are spaced away from the apertures 409. Light passing through the apertures 409 and past shutters 406 can travel through the cover plate 430 to form an image on the display. FIG. 4 further depicts a microphone 410 that is formed on the peripheral edge of the substrate 434 and the aperture layer 407. The microphone 410 includes a diaphragm 418 that is supported between springs 414 that connect to anchors 412 that couple to the aperture layer 407. The anchors 412 and springs 414 support the diaphragm 418 to be spaced away from the aperture layer 407.

The microphone 410 is aligned with the section of the cover plate 430 that is acoustically transmissive. The acoustically transmissive section allows sound waves to travel across the cover plate 430 into the microphone 410. In some implementations, the microphone 410 is located in alignment with an acoustic passage 432 formed in the cover plate 430. The acoustic passage 432 may be apertures that extend through the cover plate 430 to allow more easily acoustic energy to pass from one side of the cover plate 430 to the other side of the cover plate 430 which is proximate the microphone 410. In other implementations, the acoustic passage 432 may include a material that carries acoustic energy with sufficient accuracy and clarity to allow the microphone 410 to respond to the acoustic energy in a manner that moves the diaphragm 412 to generate electrical signals that are representative of the sounds generating the acoustic energy. In some implementations, movement of the diaphragm 412 towards and away from the aperture layer 407 changes the capacitance, or some other characteristic, of the microphone 410 and these changes in characteristics can be measured by circuits, not shown, and used to create electrical representations of the acoustic energy incident on the microphone 410.

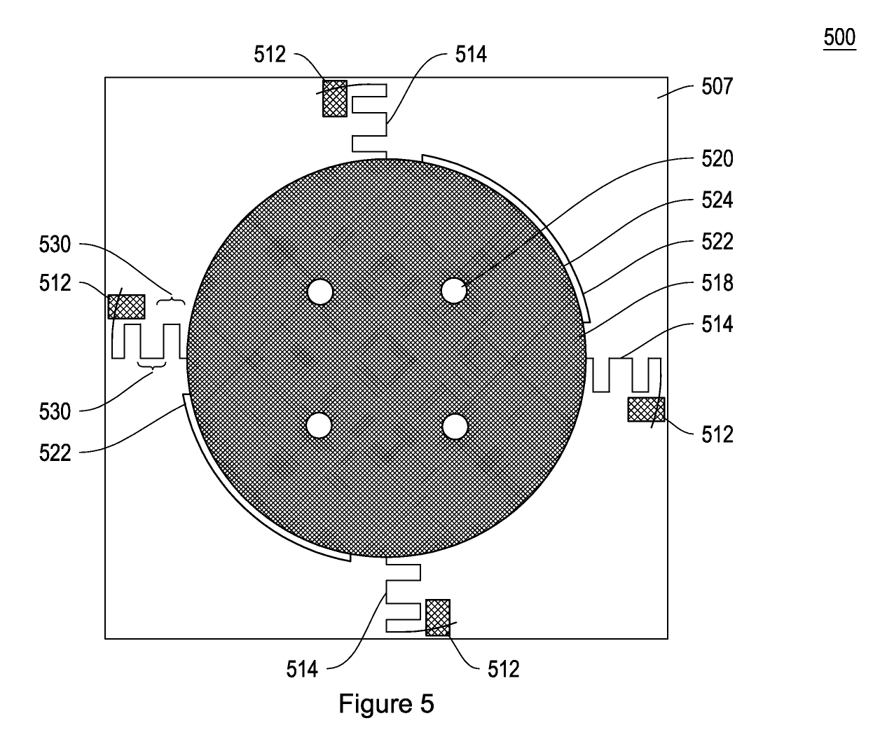

FIG. 5 is a plan view of one example of a MEMS microphone. FIG. 5 shows a MEMS microphone system 500 that includes an aperture layer 507 on which four anchors 512 are formed. The anchors 512 extend away from the surface of the aperture layer 507. Each of the anchors 512 connects to a spring 514 at one end and a second end of the spring connects to the diaphragm 518. The diaphragm 518 is a circular body having a plurality of apertures 520 defined within the diaphragm 518 and providing through holes through which air may move for the purpose of reducing air resistance as the diaphragm 518 moves toward or away from the aperture layer 507. Each of the springs 514 is formed from a beam that includes a number of sidewalls that alternate in direction. For example, 530 depicts that the beam 514 can include two parallel beams that are joined at their respective ends by a separate beam that is perpendicular to the two parallel beams. The parallel beams form a flexible connector for joining the diaphragm 518 with the anchor 512. In the implementation depicted in FIG. 5, each spring 514 includes a plurality of these joints formed from two parallel beams with an interconnected perpendicular beam joining the ends of the parallel beams. In other implementations, other structures including serpentine beam structures, beams that are V-shaped or other geometries that allow for a flexible joint may be employed without departing from the scope hereof.

The diaphragm 518 has a circular peripheral edge 524. A rib 522 connects to the peripheral edge 524 of diaphragm 518. The rib 522 may reduce or eliminate warping of the diaphragm 518, which may be a thin amorphous silicon body. In some implementations, the diaphragm 518 may be 0.1-2 mm in diamer and 0.4-4 μm in thickness. The springs 514 may be 2-40 μm in length and 1-8 μm in thickness (out-of-plane) and 0.2-2 μm in width. The anchors 512 may be 2-20 μm in-plane and 2-10 μm (out-of-plane) in height. A thin amorphous silicon disc such as the diaphragm 518 may curl or twist to an otherwise distorted shape due to internal stresses. The rib 522 may provide structural support that reduces the likelihood of the diaphragm 518 from twisting or otherwise distorting. The implementation depicted in FIG. 5 includes two ribs 522 located on opposing sides of the peripheral edge 524 of the diaphragm 518. In other implementations, a single rib 522 may be attached to the diaphragm 518, or in other implementations more than two ribs 522 may attach to the peripheral edge 524 of the diaphragm 518. The diaphragm 518 is a circular disc but in other implementations, it may be other shapes.

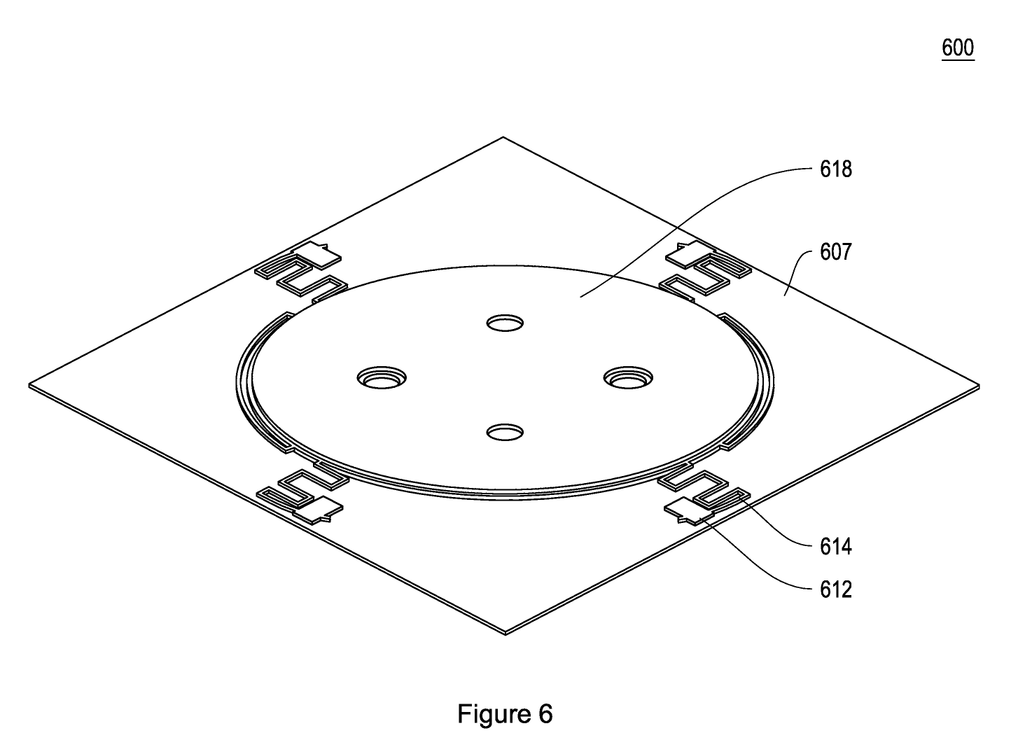

FIG. 6 shows a perspective view of one example of a MEMS microphone. FIG. 6 shows a MEMS microphone assembly 600 that includes a diaphragm 618 supported by four anchors 612 with four respective springs 614 connecting the diaphragm 618 to the individual anchors 612. The perspective view shows that the anchors 612 extend away from the surface of the aperture layer 607 and the springs 614 hold the diaphragm 618 away from the aperture layer 607. In some implementations the diaphragm is 1-6 μm from the aperture layer 607, although other distances may be used. The anchor 612 can couple to an electrical ground plane (not shown) and an electrical potential may be applied to the anchor 612, the spring 614 and in consequence, the diaphragm 618. Noise traveling through the acoustic channel 432 can act against the surface 618 of the diaphragm, driving the diaphragm 618 towards and away from the aperture layer 607. The springs 614 provide sufficient flexibility to allow the diaphragm 618 to respond to the acoustic signals normally generated when a person speaks. In some implementations, the spring constant is between about 0.1-100N/m. The stiffness is generally higher than conventional microphones which allows them to survive mechanical shock and provides vibration immunity or resistance. The surface of the actuator 607 may couple to a second electrode (not shown) and the relative capacitances of the space between the diaphragm 618 and aperture 607 may be measured. As that space changes due to the impact of acoustic energy against the surface of the diaphragm 618, the changes may be employed to record, or otherwise use the acoustic signals generated by the microphone 600.

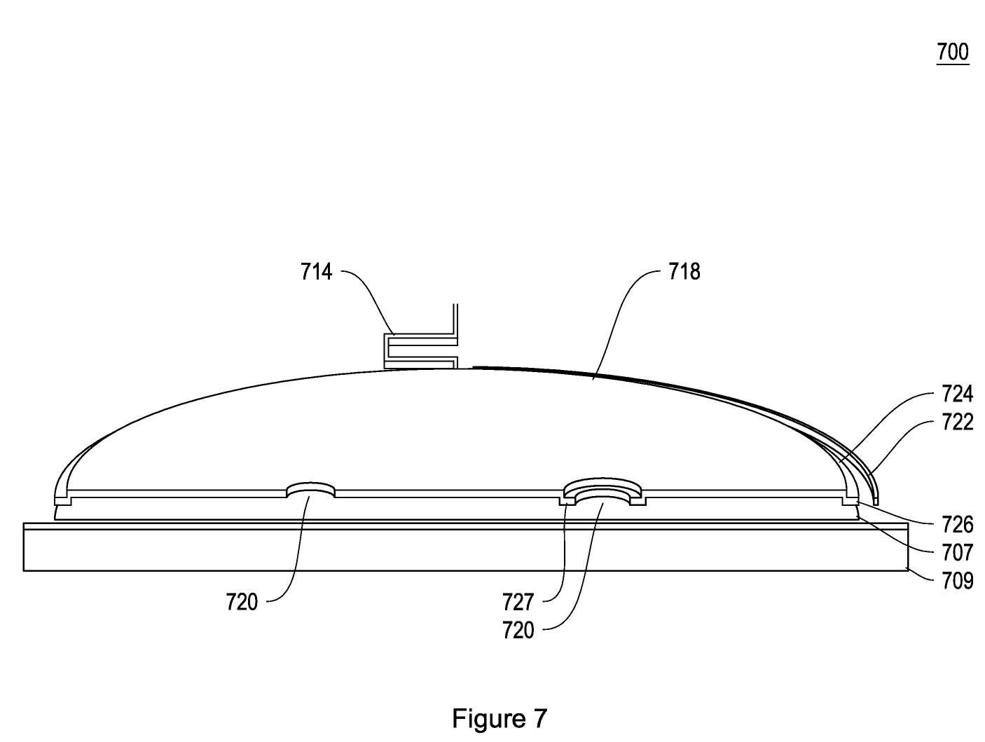

FIG. 7 shows a cross-sectional view of the MEMS microphone of FIG. 5. The MEMS microphone assembly 700 includes the diaphragm 718 shown in cross-section and the apertures 720 also shown in cross-section. At the peripheral edge 724 of the diaphragm 718, the rib 722 may be attached and connected to help reduce the likelihood that the diaphragm 718 will fold or curl or distort. The peripheral edge 724 of the diaphragm 718 may also include a lip 726 that faces the aperture layer 707 which is formed on the substrate 709. The lip 726 is shown in cross-section but, in this implementation, the lip may extend along the entire peripheral edge 724 of the diaphragm 718. The apertures 720 may have an interior peripheral edge, which in this implementation is a circular edge. Optionally, a lip 727 may be formed around the interior peripheral edge of an aperture 720 and provide a lip that extends away from the surface of the diaphragm 718 and faces the aperture layer 707 on the substrate 709. Both of the lips 726 and 727 are spaced closer to the aperture layer 707 than the diaphragm body 718. As such, the lips 726 and 727 can contact the aperture layer 707, and prevent or reduce the likelihood that the diaphragm 718 will make contact with the aperture surface 707. The contacting of the smaller surface areas provided by these lips 726 and 727 has a tendency to reduce stiction between the diaphragm 718 and the aperture layer of 707. This can provide for more robust and reliable operation of the microphone 700.

The spring 714 may be a sidewall beam formed as part of the aperture layer 707 deposited on the substrate 709. The sidewall beam 714 may be formed during the processing of the aperture layer 707 as apertures and shutters are formed for the display elements. In certain implementations the shutter actuators, such as the actuators 202 depicted in FIG. 2, also include sidewall beams as movable components. The sidewall beam in one implementation, is a beam formed from a layer of structural material. A sidewall beam is formed by operations that include conformally depositing structural material over a removable mold disposed on a substrate, wherein the mold includes horizontal surfaces and one or more vertical surfaces, selectively removing the structural material from horizontal surfaces of the mold (such as by way of a directional etch), and removing the mold. A sidewall beam has a horizontal dimension that is substantially equal to the thickness of a structural layer material as deposited on a vertical sidewall beam of a removable mold. The sidewall beam is separated from a substrate by a gap after removal of the mold. A sidewall beam is typically characterized by a height-to-width aspect ratio greater than one, wherein height is the dimension of the beam in the vertical direction and width is the narrower of the dimensions of the beam in the horizontal direction. In some implementations, the sidewall beam that is used as a spring in the MEMS microphones has a height-to-width aspect ratio of about four to one, or a height-to-width aspect ratio of about sixteen to one.

As used herein, the terms “horizontal” and “vertical” depend on the orientation of the substrate. “Horizontal” is defined as substantially parallel to the plane defined by the major dimension of the substrate, and “vertical” is defined as substantially orthogonal to the plane defined by the major dimension of the substrate.

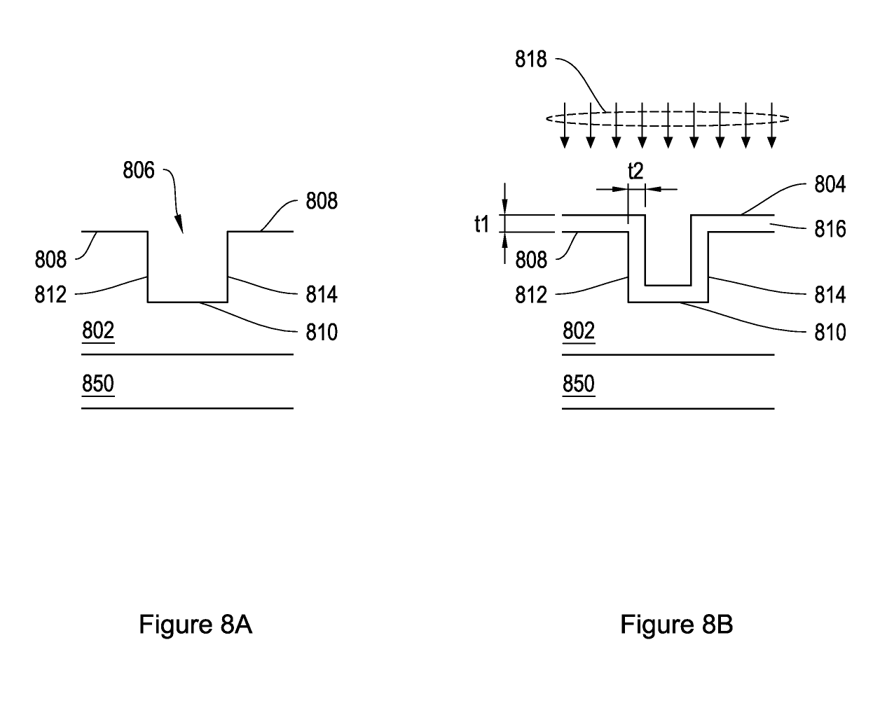

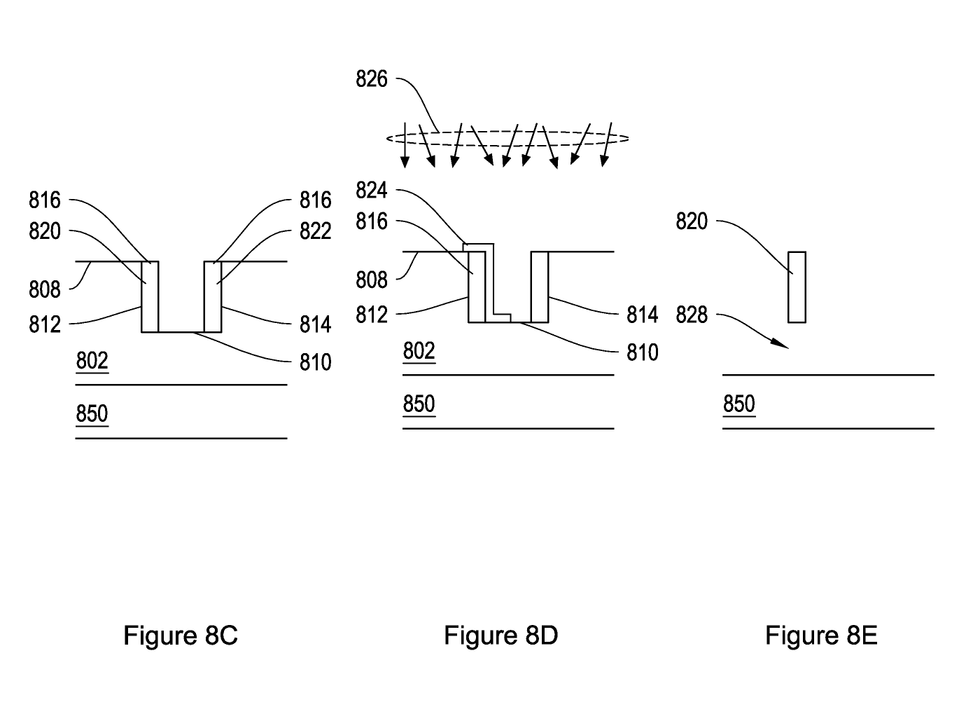

FIGS. 8A-8E depict schematic drawings of a cross-sectional view of a region of a substrate including a sidewall beam at different stages of fabrication in one exemplary implementation. The fabrication or processing shown in FIGS. 8A-8E represents the types of processing operations that may be used to form the display elements and the microphone that are carried on the surface of the substrate. FIG. 8A depicts a mold 800 for the sidewall beam of the microphone spring, which is formed by depositing sacrificial layer 802 on substrate 850 and forming feature 806 in the sacrificial layer 802. The feature 806 is a substantially U-shaped channel that includes a horizontal top surface 808, a horizontal bottom surface 810, and vertical sidewall beams 812 and 814. The sacrificial layer 802 is a material that can be selectively removed over the structural material that composes the sidewall beam. Anchors and springs for the microphone may be formed during the same process steps as the shutter actuators, such as actuators 202 and 204 of FIG. 2.

In various implementations, the sacrificial layer 802 has a thickness within the range of about 0.2 microns to about 5 microns, or within the range of about 0.2 microns to about 10 microns. In one implementation, the sacrificial layer 802 is fully hardened at an elevated temperature so that it is no longer photolithographically patterned. In some implementations, a second sacrificial layer is formed on the sacrificial layer 802, to allow for the formation of additional features such as anchors, tethers, shuttles, and sidewall beams.

A photo-definable polyimide may be used as the material for the sacrificial layer 802 because it can be easily patterned using conventional photolithographic techniques. Further, it can be readily removed during a release etch using a conventional plasma etch or non-directional reactive-ion etch. In other applications, other materials may be used for the sacrificial layer 802, such as phenol-formaldehyde resins, polymers, photoresists, non-photo-definable polyimides, glasses, semiconductors, metals, and dielectrics. In one example, the material used for the sacrificial layer 802 is a phenol-formaldehyde resins with a formaldehyde to phenol molar ratio of less than one, such as a Novolac resin. The choice of the material for the sacrificial layer 802 may be based on many considerations, such as its etch selectivity over other materials in the overall structure, its ability to maintain its shape at elevated temperatures, the relative ease with which it can be shaped and/or patterned, process thermal budget, deposition temperature, and the choice of structural material used for elements within the complete device.

FIG. 8B depicts the region of the mold 800 after the deposition of the structural layer 804 on the mold 800. The structural layer 804 includes a structural material 816. The structural layer 804 is deposited such that it is conformal with the underlying sacrificial layer 802 and the U-shaped feature 806. As a result, the structural material 816 is disposed as a continuous layer that includes horizontal portions disposed on each of the top surfaces 808 and the bottom surface 810, and vertical portions disposed on the sidewall beams 812 and 814. The as-deposited layer thickness of the horizontal portions of the structural layer 804 (i.e., the thickness of the structural material 816 disposed on each of the top surface 808 and the bottom surface 810) is equal to thickness t1, while the as-deposited layer thickness of the vertical portions of the structural layer 804 (i.e., the thickness of the structural material 816 disposed on each of the sidewall beams 812 and 814) is equal to the thickness t2.

In one example, the structural layer 804 is a layer of amorphous silicon having a thickness of approximately 0.4 micron and is substantially uniform on all exposed surfaces (i.e., each of t1 and t2 is substantially equal to 0.4 micron). In other examples, the thickness of the structural layer 804 is within the range of approximately 0.01 micron to 5 microns. In some examples, t1 and t2 are not the same. The thickness of structural layer 804 influences the reliability and performance (for example, resiliency, sensitivity, and stiffness) of the microphone. Thus, for example, the thickness of the structural layer 804 may be based on the desired mechanical behavior of the diaphragm and the microphone. In various implementations, the structural layer 804 may have any thickness. Additionally, in some implementations, the structural layer 804 may include any suitable material, such as polysilicon, silicon carbide, dielectrics, metals, glasses, ceramics, dielectrics, germanium, III-V semiconductors, and II-VI semiconductors.

The structural layer 804 is deposited such that it is conformal with the mold formed by the underlying sacrificial layer 802. The deposition of the structural layer 804 results in the formation of vertical elements, which are nascent sidewall beams 812 and 814.

A first layer is substantially conformal with an underlying second layer when it is disposed as a continuous layer on the exposed surfaces of a second layer such that the first layer and second layer have substantially the same shape. In some implementations, the as-deposited layer thickness of the first layer is substantially uniform on all of the surfaces of the second layer on which it is deposited (i.e., t1 and t2 are substantially equal). Uniformity of the as-deposited layer thickness can be affected by, for example, choice of deposition method, precursor gasses, and deposition conditions. As a result, a substantially conformal layer can have some variation in its thickness between portions of the layer disposed on horizontal surfaces and portions of the layer disposed on substantially vertical surfaces. The variation is typically within one order of magnitude (i.e., t1≦10*t2).

After its deposition, the layer 804 is etched in an etch 818. The etch 818 is a highly directional etch that removes structural material from exposed horizontal surfaces but does not appreciably affect structural material disposed on vertical surfaces. Therefore, the etch 818 removes structural material 816 from the top surface 808 and the bottom surface 810 but not the sidewall beams 812 and 814. In some implementations, etchants used in directional etching may include a plasma of reactive gases such as fluorocarbons, oxygen, chlorine, and/or boron trichloride. In some applications, other gases may be added to the plasma or reactive gases, such as nitrogen, argon, and/or helium.

FIG. 8C depicts the region of the mold 800 after the etch 818. After the etch 818, the structural material 816 remains on the sidewalls 812 and 814. The structural material 816 on the sidewall 812 represents a first nascent sidewall beam 820. Similarly, the structural material 816 on the sidewall 814 represents a second nascent sidewall beam 822. From the cross-sectional view of FIG. 8C, the aspect ratio is presented. In some implementations, the aspect ratio of the sidewall beams 820 and 822 is between about 4:1 and 16:1, height to width. In some implementations, each of the first 820 and second 822 sidewall beams are design elements of a micromechanical device, such as a microphone or a shutter actuator. In such implementations, the mold 800 can be removed at this point. In some implementations, however, one of the first 820 and second 822 nascent sidewall beams is removed prior to removal of the mold 800.

FIG. 8D depicts the removal of one sidewall beam. A mask layer 824 is disposed over the structural material disposed on the sidewall beam 812 to protect the structural material from attack in the etch 826. The etch 826 is a non-directional etch suitable for removing exposed structural material. Thus, the etch 826 removes structural material from exposed surfaces without regard to the orientation of the surface. As a result, the etch 826 removes structural material 816 from the sidewall beam 814. The non-directional etch may be an isotropic etchant, such as a corrosive liquid or a chemically active ionized gas, such as a plasma.

FIG. 8E depicts the fully formed and released first sidewall beam 820. After the removal of the sacrificial layer 802, the sidewall beam 820 is free from the substrate 850 and is separated from the substrate 850 by an air gap 828.

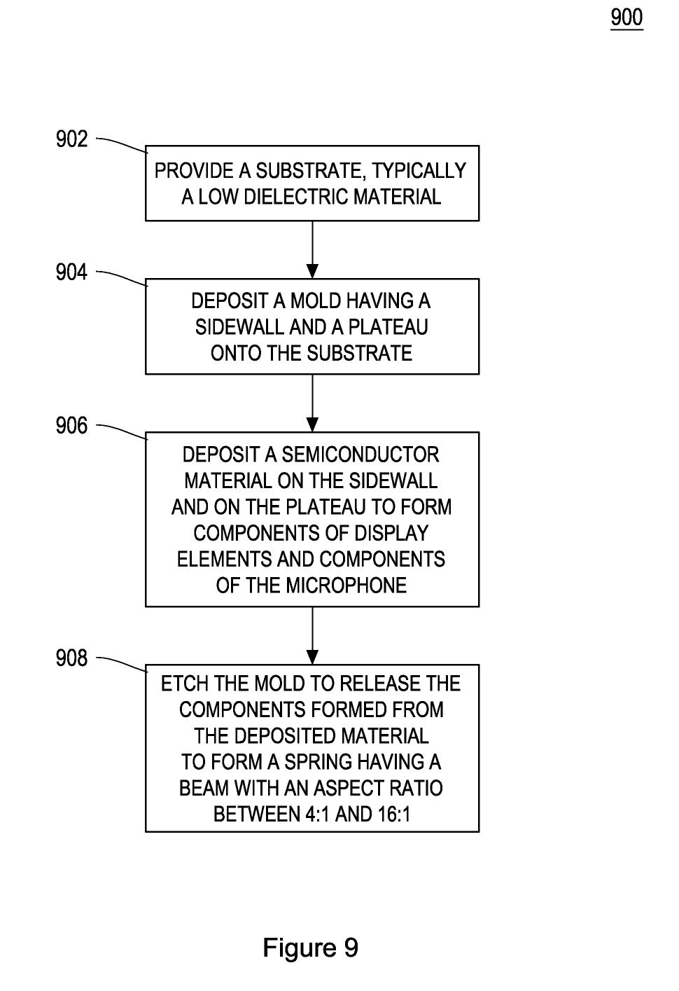

FIG. 9 is a flowchart diagram of one example of a process for forming a MEMS microphone. FIG. 9 illustrate a manufacturing process 900 that, in operation 902, provides a substrate. The substrate can be a low dielectric substrate, such as a glass or plastic material that has a dielectric characteristic lower than the dielectric characteristic of amorphous silicon. In implementations where the microphone is being integrated into a display, the process may use the substrate that will act as the substrate for the display element that will modulate the light and form images on the display.

The process 900 in operation 904 deposits a semiconductor material to form a mold on the substrate. In one implementation, a layer of amorphous silicon material is deposited across substantially an entire surface of the substrate. The amorphous silicon material may be deposited over an interconnect layer that extends under the locations selected for the display elements and microphone or microphones being formed. The layer of amorphous silicon may be deposited using a pattern or mask, to form features that will support subsequent deposition layers that will form the components of the microphones and the display elements being formed on the substrate. To that end, the mold may have features, such as the U-shaped feature illustrated in FIG. 8B, that provide sidewalls and plateaus onto the substrate. In operation 906, the process 900 can deposit a semiconductor material on the sidewall and onto the plateau. In operation 908, the process 900 may etch the mold to release the material deposited on the sidewall and the plateau to thereby form a spring attached to a diaphragm.

Optionally, the process may provide a cover plate, such as the cover plate 430 shown in FIG. 4, that has a transparent section that can cover the display elements and an acoustically trans missive section that can cover the microphone.

Once formed, the process 900 may connect a portion of the deposited silicon layer that is proximate and beneath the diaphragm, to a ground plane and can connect the diaphragm to a different voltage level. Motion of the diaphragm toward and away from the grounded silicon layer can change the capacitance between the diaphragm and the grounded silicon layer and these changes in capacitance will modulate a signal passing through the diaphragm. The modulated signal may be used to sense acoustic signals acting on the diaphragm.

Optionally, the process 900 may form on the diaphragm a lip facing the substrate and extending along a peripheral edge of the diaphragm. Further optionally, the process 900 may form a rib connected to a peripheral edge of the diaphragm for reducing warping of the substrate. Optionally, the process 900 may also form a plurality of apertures within the diaphragm. The apertures, or holes, can have a size suitable for reducing air resistance as the diaphragm moves toward the substrate.

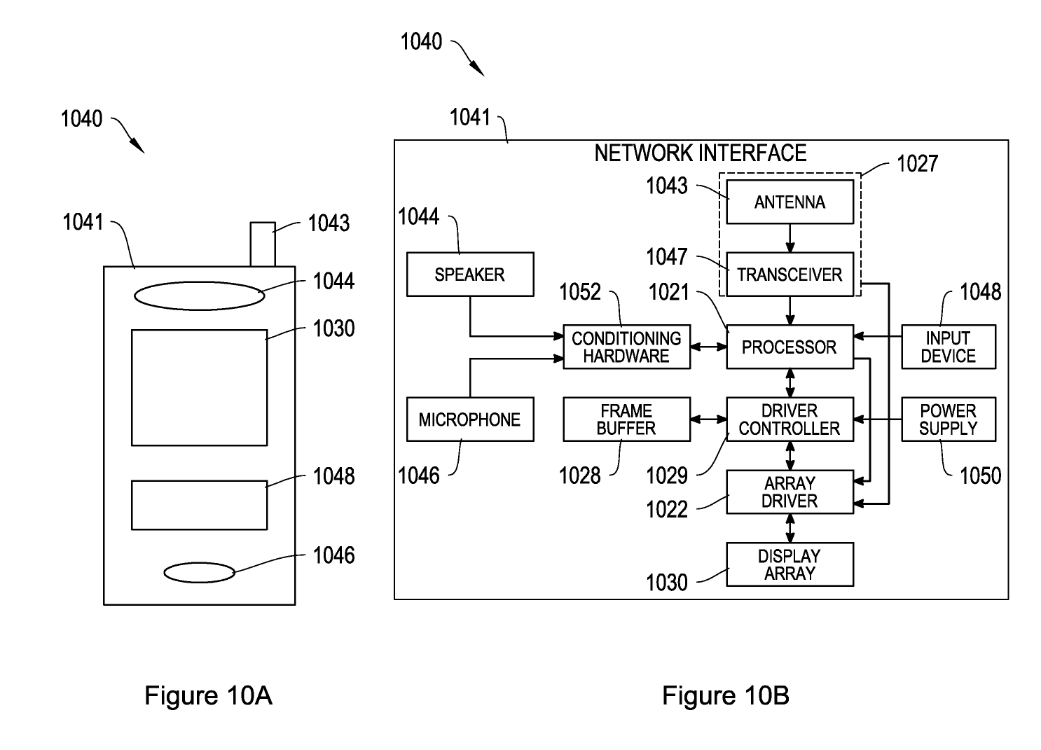

FIGS. 10A and 10B show system block diagrams of an example display device 1040 that includes a plurality of display elements. The display device 1040 can be, for example, a smart phone, a cellular or mobile telephone. However, the same components of the display device 1040 or slight variations thereof are also illustrative of various types of display devices such as televisions, computers, tablets, e-readers, hand-held devices and portable media devices.

The display device 1040 includes a housing 1041, a display 1030, an antenna 1043, a speaker 1045, an input device 1048 and a microphone 1046. The housing 1041 can be formed from any of a variety of manufacturing processes, including injection molding, and vacuum forming. In addition, the housing 1041 may be made from any of a variety of materials, including, but not limited to: plastic, metal, glass, rubber and ceramic, or a combination thereof. The housing 1041 can include removable portions (not shown) that may be interchanged with other removable portions of different color, or containing different logos, pictures, or symbols.

The display 1030 may be any of a variety of displays, including a bi-stable or analog display, as described herein. The display 1030 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 1030 can include a mechanical light modulator-based display, as described herein.

The components of the display device 1040 are schematically illustrated in FIG. [10B]. The display device 1040 includes a housing 1041 and can include additional components at least partially enclosed therein. For example, the display device 1040 includes a network interface 1027 that includes an antenna 1043 which can be coupled to a transceiver 1047. The network interface 1027 may be a source for image data that could be displayed on the display device 1040. Accordingly, the network interface 1027 is one example of an image source module, but the processor 1021 and the input device 1048 also may serve as an image source module. The transceiver 1047 is connected to a processor 1021, which is connected to conditioning hardware 1052. The conditioning hardware 1052 may be configured to condition a signal (such as filter or otherwise manipulate a signal). The conditioning hardware 1052 can be connected to a speaker 1045 and a microphone 1046. The processor 1021 also can be connected to an input device 1048 and a driver controller 1029. The driver controller 1029 can be coupled to a frame buffer 1028, and to an array driver 1022, which in turn can be coupled to a display array 1030. One or more elements in the display device 1040, including elements not specifically depicted in FIG. [10A], can be capable of functioning as a memory device and be capable of communicating with the processor 1021. In some implementations, a power supply 1050 can provide power to substantially all components in the particular display device 1040 design.

The network interface 1027 includes the antenna 43 and the transceiver 1047 so that the display device 1040 can communicate with one or more devices over a network. The network interface 1027 also may have some processing capabilities to relieve, for example, data processing requirements of the processor 1021. The antenna 1043 can transmit and receive signals. In some implementations, the antenna 1043 transmits and receives RF signals according to any of the IEEE 16.11 standards, or any of the IEEE 802.11 standards. In some other implementations, the antenna 1043 transmits and receives RF signals according to the Bluetooth® standard. In the case of a cellular telephone, the antenna 1043 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 1047 can pre-process the signals received from the antenna 1043 so that they may be received by and further manipulated by the processor 1021. The transceiver 1047 also can process signals received from the processor 1021 so that they may be transmitted from the display device 1040 via the antenna 1043.

In some implementations, the transceiver 1047 can be replaced by a receiver. In addition, in some implementations, the network interface 1027 can be replaced by an image source, which can store or generate image data to be sent to the processor 1021. The processor 1021 can control the overall operation of the display device 1040. The processor 1021 receives data, such as compressed image data from the network interface 1027 or an image source, and processes the data into raw image data or into a format that can be readily processed into raw image data. The processor 1021 can send the processed data to the driver controller 1029 or to the frame buffer 1028 for storage. Raw data typically refers to the information that identifies the image characteristics at each location within an image. For example, such image characteristics can include color, saturation and gray-scale level.

The processor 1021 can include a microcontroller, CPU, or logic unit to control operation of the display device 1040. The conditioning hardware 1052 may include amplifiers and filters for transmitting signals to the speaker 1045, and for receiving signals from the microphone 1046. The conditioning hardware 1052 may be discrete components within the display device 1040, or may be incorporated within the processor 1021 or other components.

The driver controller 1029 can take the raw image data generated by the processor 21 either directly from the processor 1021 or from the frame buffer 1028 and can re-format the raw image data appropriately for high speed transmission to the array driver 1022. In some implementations, the driver controller 1029 can re-format the raw image data into a data flow having a raster-like format, such that it has a time order suitable for scanning across the display array 1030. Then the driver controller 1029 sends the formatted information to the array driver 1022. Although a driver controller 1029 is often associated with the system processor 1021 as a stand-alone Integrated Circuit (IC), such controllers may be implemented in many ways. For example, controllers may be embedded in the processor 1021 as hardware, embedded in the processor 1021 as software, or fully integrated in hardware with the array driver 1022.

The array driver 1022 can receive the formatted information from the driver controller 1029 and can re-format the video data into a parallel set of waveforms that are applied many times per second to the hundreds, and sometimes thousands (or more), of leads coming from the display's x-y matrix of display elements. In some implementations, the array driver 1022 and the display array 1030 are a part of a display module. In some implementations, the driver controller 1029, the array driver 1022, and the display array 1030 are a part of the display module.

In some implementations, the driver controller 1029, the array driver 1022, and the display arrayl030 are appropriate for any of the types of displays described herein. For example, the driver controller 1029 can be a conventional display controller or a bi-stable display controller (such as a mechanical light modulator display element controller). Additionally, the array driver 1022 can be a conventional driver or a bi-stable display driver (such as a mechanical light modulator display element controller). Moreover, the display array 1030 can be a conventional display array or a bi-stable display array (such as a display including an array of mechanical light modulator display elements). In some implementations, the driver controller 1029 can be integrated with the array driver 1022. Such an implementation can be useful in highly integrated systems, for example, mobile phones, portable-electronic devices, watches or small-area displays.

In some implementations, the input device 1048 can be configured to allow, for example, a user to control the operation of the display device 1040. The input device1048 can include a keypad, such as a QWERTY keyboard or a telephone keypad, a button, a switch, a rocker, a touch-sensitive screen, a touch-sensitive screen integrated with the display array 1030, or a pressure- or heat-sensitive membrane. The microphone 1046 can be configured as an input device for the display device 1040. In some implementations, voice commands through the microphone 1046 can be used for controlling operations of the display device 1040. Additionally, in some implementations, voice commands can be used for controlling display parameters and settings.

The power supply 1050 can include a variety of energy storage devices. For example, the power supply 1050 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 1050 also can be a renewable energy source, a capacitor, or a solar cell, including a plastic solar cell or solar-cell paint. The power supply 1050 also can be configured to receive power from a wall outlet.

In some implementations, control programmability resides in the driver controller 1029 which can be located in several places in the electronic display system. In some other implementations, control programmability resides in the array driver 1022. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A microphone, comprising
a substrate,
a plurality of anchors attached to the substrate and extending away from the substrate,
a diaphragm, and
a plurality of springs each having a first end connected to a respective anchor and a second end connected to the diaphragm to hold the diaphragm away from the substrate, and each having a beam with a cross-section having an aspect ratio of greater than 4:1 and extending from the anchor to the diaphragm.

2. The microphone of claim 1, wherein the aspect ratio is between 4:1 and 16:1.

3. The microphone of claim 1, wherein the substrate comprises a low dielectric material.

4. The microphone of claim 1, further comprising a lip facing the substrate and extending along a peripheral edge of the diaphragm.

5. The microphone of claim 1, further comprising a rib connected to a peripheral edge of the diaphragm to reduce warping of the substrate.

6. The microphone of claim 1, further comprising a plurality of apertures formed on the diaphragm to reduce air resistance as the diaphragm moves toward the substrate.

7. The microphone of claim 6, further comprising a wall formed along a peripheral edge of an aperture and facing the substrate.

8. The microphone of claim 1, wherein one of the plurality of springs includes two parallel beams joined at respective ends of the beams to form a flexible connector.

9. The microphone of claim 1, wherein the beam and the diaphragm are integrally formed from a layer of semiconductor material.

10. The microphone of claim 1, further comprising:
a plurality of display elements formed on the substrate to form a display on the substrate;
a processor capable of communicating with the display, the processor being capable of processing image data; and
a memory device capable of communicating with the processor.

11. The microphone of claim 10, wherein
the display elements and the plurality of springs comprise a continuous layer of semiconductor material deposited upon the substrate.

12. The microphone of claim 10, further comprising:
a driver circuit capable of sending at least one signal to the display; and
a controller capable of sending at least a portion of the image data to the driver circuit.

13. The microphone of claim 10, further comprising:
an image source module capable of sending the image data to the processor, wherein the image source module includes at least one of a receiver, transceiver, and transmitter.

14. The microphone of claim 10, further comprising:
an input device capable of receiving input data and communicating the input data to the processor.

15. A method for manufacturing a microelectromechanical systems microphone, comprising:
providing a substrate,
depositing a mold having a sidewall and a plateau onto the substrate,
depositing a semiconductor material on the sidewall and on the plateau, and
etching the mold to release the material deposited on the sidewall and the plateau to thereby form a spring attached to a diaphragm.

16. The method of claim 15, wherein providing a substrate includes providing a low dielectric substrate.

17. The method of claim 15, wherein forming a spring includes: forming a silicon beam having a cross-sectional aspect ratio between 4:1 and 16:1; and forming a passivation layer.

18. The method of claim 15, wherein depositing a semiconductor material includes depositing the semiconductor material on the substrate to form a plurality of display elements.

19. The method of claim 18, further comprising
providing a cover plate have a transparent section and sized to cover the plurality of display elements and an acoustically transmissive section and sized to cover the diaphragm.

20. The method of claim 15, further comprising
connecting a portion of the substrate proximate the diaphragm to a ground plane.

21. The method of claim 15, wherein depositing a semiconductor material on the sidewall includes depositing a semiconductor material on a plurality of interconnects to provide a flexible connection to the diaphragm.

22. The method of claim 15, further comprising
forming on the diaphragm a lip facing the substrate and extending along a peripheral edge of the diaphragm.

23. The method of claim 15, further comprising forming a rib connected to a peripheral edge of the diaphragm to reduce warping of the substrate.

24. The method of claim 15, further comprising:
forming a plurality of apertures within the diaphragm and to reduce air resistance as the diaphragm moves toward the substrate.

25. A display, comprising
a substrate having a continuous layer of semiconductor material deposited thereon to form an array of display elements and a microphone having a movable diaphragm, and
a cover plate having a transparent section and an acoustically transmissive section, the cover plate being disposed to face the substrate and align the transparent section with the array of display elements and the acoustically transmissive section with the microphone.

26. The display of claim 25 further comprising
a spring having a first end connected to the movable diaphragm and a second end connected to an anchor connected to the substrate, and having a beam with a cross-sectional aspect ratio of greater than 4:1.

27. The display of claim 26, wherein the spring includes two parallel beams joined at respective ends of the beams to form a flexible connector.
